(19) United States
(12) Patent Application Publication
(10) Pub. No.: US 2025/0379189 A1
(43) Pub. Date: Dec. 11, 2025

(54) ENHANCED THERMAL SOLUTION FOR STACKED CACHE DIE CONFIGURATION

(71) Applicant: International Business Machines Corporation, Armonk, NY (US)

(72) Inventors: Mukta Ghate Farooq, HOPEWELL JCT, NY (US); Aakrati Jain, Albany, NY (US); Prabudhya Roy Chowdhury, Albany, NY (US); Sathyanarayanan Raghavan, Ballston Lake, NY (US); Katsuyuki Sakuma, Fishkill, NY (US)

(21) Appl. No.: 18/740,488

(22) Filed: Jun. 11, 2024

(51) Int. Cl. H01L 25/065; H01L 23/00; H01L 25/18

(52) U.S. Cl. CPC H01L 25/0657; H01L 24/05; H01L 24/16; H01L 24/19; H01L 24/32; H01L 24/83; H01L 25/18; H01L 2224/05647; H01L 2224/16225; H01L 2224/19; H01L 2224/32225; H01L 2224/83895; H01L 2225/06589; H01L 2924/1437

(57) ABSTRACT

A stacked assembly includes a first semiconductor die; a second semiconductor die secured to the first semiconductor die; and a dielectric encasing at least the second semiconductor die. The dielectric defines a cooling channel having at least one inlet and at least one outlet, and the cooling channel is configured to direct cooling fluid to at least the second semiconductor die.

### BACKGROUND

The present invention relates generally to the electrical, electronic and computer arts and, more particularly, to three-dimensional stacking of integrated circuit dies.

The stacking of dies is proposed to enhance packaging density. However, die stacking may pose thermal management issues.

### BRIEF SUMMARY

Principles of the invention provide techniques for an enhanced thermal solution for stacked cache die configuration. In one aspect, an exemplary stacked assembly includes a first semiconductor die; a second semiconductor die secured to the first semiconductor die; and a dielectric encasing at least the second semiconductor die. The dielectric defines a cooling channel having at least one inlet and at least one outlet. The cooling channel is configured to direct cooling fluid to at least the second semiconductor die.

In another further aspect, an exemplary method for forming a stacked assembly includes providing a first assembly including a first semiconductor die and a second semiconductor die secured to the first semiconductor die, where the first semiconductor die extends horizontally beyond the second semiconductor die; depositing a first dielectric layer at least on a peripheral surface of the first semiconductor die; patterning and etching the first dielectric layer to form at least one cooling channel; depositing a sacrificial layer in the at least one cooling channel; and forming a layer of ultraviolet-transparent material above the at least one cooling channel. Further steps include applying ultraviolet radiation to the sacrificial layer through the layer of ultraviolet-transparent material to cause gasification and removal of the sacrificial material; and depositing a second dielectric layer outward of the layer of ultraviolet-transparent material to at least partially enclose the at least one cooling channel, to produce a second assembly.

As used herein, “facilitating” an action includes performing the action, making the action easier, helping to carry the action out, or causing the action to be performed. Thus, by way of example and not limitation, instructions executing on one processor might facilitate an action or actions carried out by instructions executing on a remote processor, an action or actions carried out by semiconductor fabrication equipment, an action or actions carried out by a pump, fan, or blower, or the like, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments provide enhanced thermal performance.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 shows a top view of an enhanced thermal solution in accordance with an aspect of the invention;

FIG. 2 is a cross-section along line II-II in FIG. 1;

FIG. 3 is a cross-section along line III-III in FIG. 1;

FIGS. 4-16 show steps in an exemplary process flow in accordance with aspects of the invention, wherein FIG. 10B is a top view and FIGS. 4-10A and FIGS. 11-16 are cross-sectional views;

FIG. 17 shows a cross-sectional view of another enhanced thermal solution in accordance with an aspect of the invention; and

FIG. 18 shows a cross-sectional view of still another enhanced thermal solution in accordance with an aspect of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

One or more embodiments provide a structure and process for an enhanced thermal solution for a stacked cache die configuration.

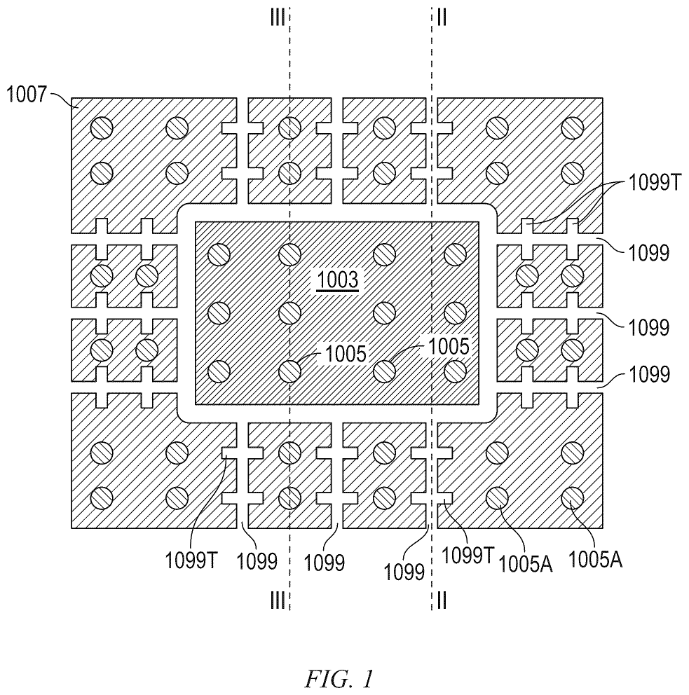

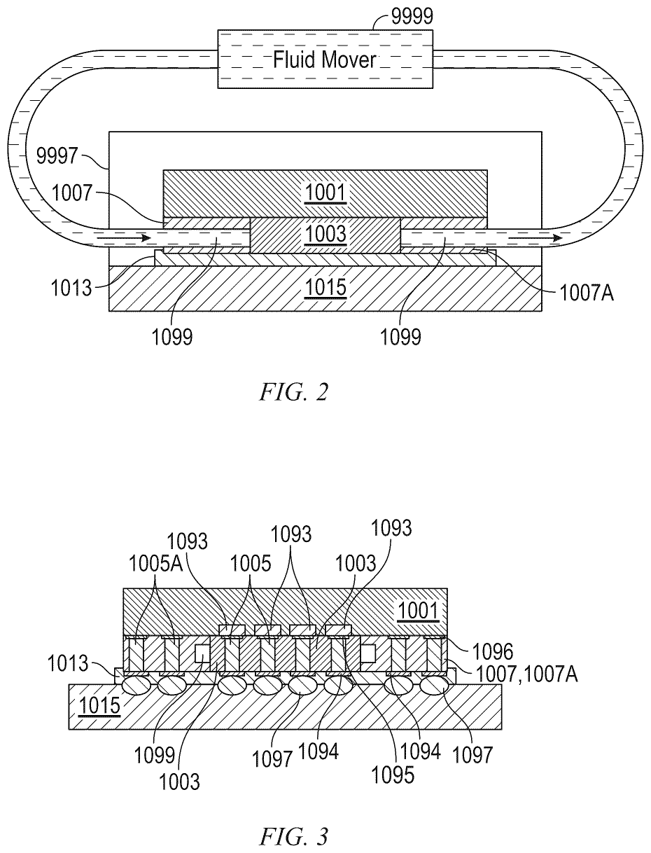

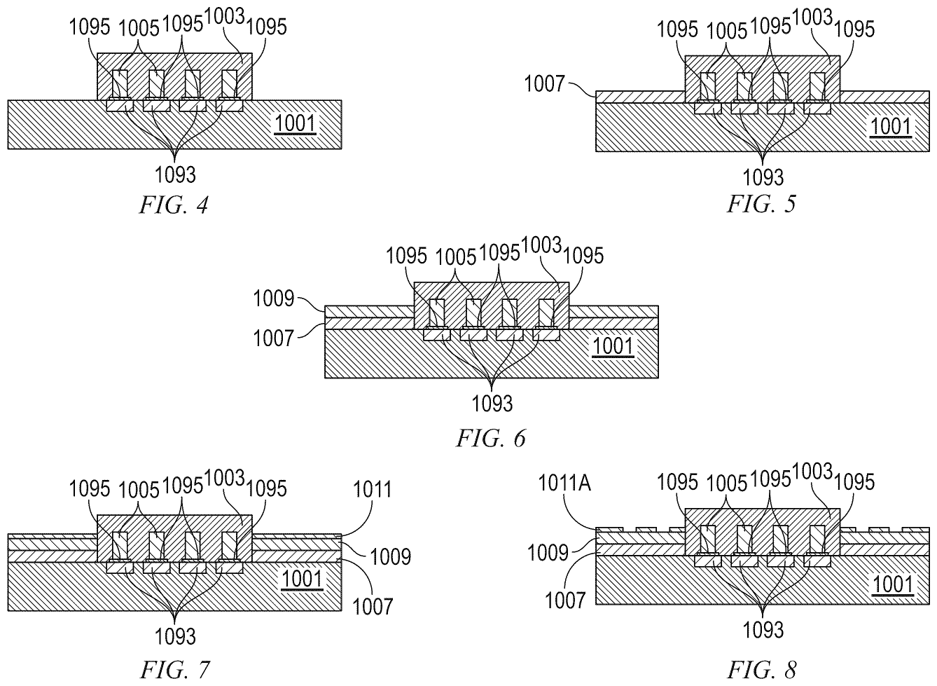

FIG. 1 shows a top view of an enhanced thermal solution in accordance with an aspect of the invention. FIG. 2 is a cross-section along line II-II in FIG. 1 and FIG. 3 is a cross-section along line III-III in FIG. 1. Note the laminate 1015, underfill 1013 (epoxy compound is a non-limiting example), first dielectric 1007, second dielectric 1007A, static random access memory (SRAM) die 1003, and logic wafer 1001, through-silicon vias 1005 and through-device vias 1005A. Referring particularly to FIG. 3, note the channel 1099 in the dielectric and the solder bumps 1097. In a non-limiting example, the solder bumps 1097 are C4 (controlled collapse chip connection) bumps. Elements 1093, 1094, 1095, and 1096 are discussed further below.

In FIG. 2, noted the fluid mover (e.g., pump, fan, blower) 9999 and lid 9997 with an inlet duct (not separately numbered) passing through the lid to supply cooling fluid (symbolized by inbound arrow) and an outlet duct (not separately numbered) passing through the lid to receive cooling fluid (symbolized by outbound arrow).

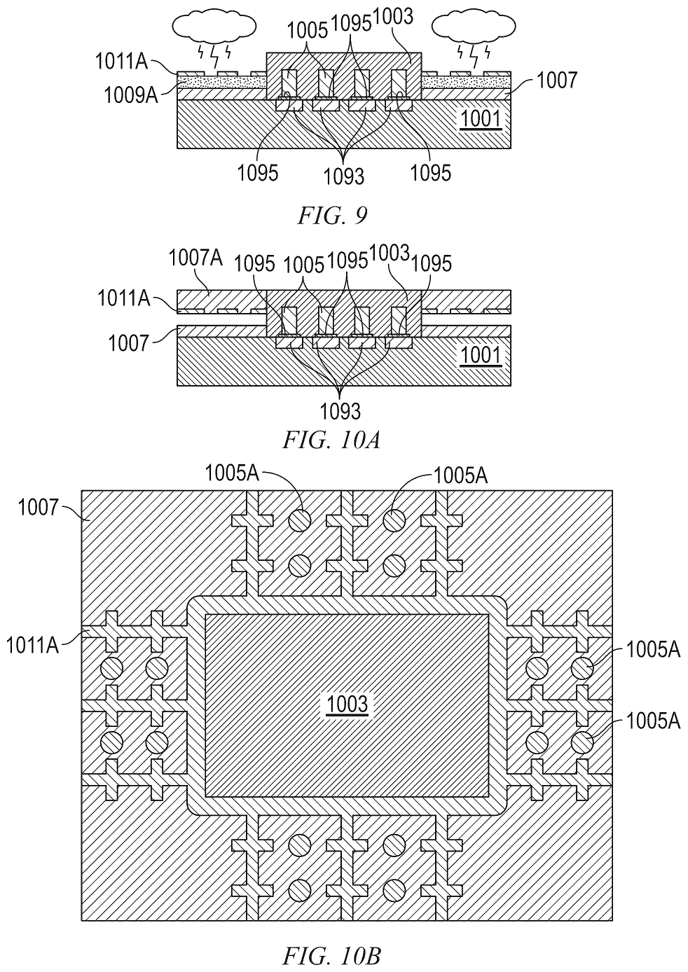

An exemplary process flow begins in FIG. 4 for an enhanced thermal solution with embedded channels. Note the logic wafer 1001, SRAM die 1003, and vias 1005 (e.g., copper). A full logic wafer device-to-wafer (D2W) join of the logic wafer to the SRAM die is carried out front-to-front (F2F); for example, using 4 μm pitch Cu hybrid bonding. The through-silicon vias (TSVs) 1005 may not be revealed but the die 1003 may be thinned to about 18-20 μm. Note the TSV landing pads 1095. The pads 1095 bond to the adjoining pads 1093 on the wafer.

In FIG. 5, deposit oxide 1007 (e.g., 18 μm thickness). The oxide 1007 can, for example, be deposited everywhere, including around the die, and then be ground off to produce the depicted structure. This is followed by steps to create the cooling channel 1099 in between the two oxide layers as will be discussed below. The oxide 1007 is patterned to create the cooling channel 1099 (see, e.g., top view in FIG. 1). T-shaped wider regions 1099T are discussed below.

In FIG. 6, deposit SiCOH 1009 in the trenches (to become the cooling channel 1099 seen in FIG. 1) that resulted from the patterning. The SiCOH 1009 visible in FIG. 6 is overburden and also fills the trenches.

In FIG. 7, deposit ultraviolet (UV) transparent material 1011 above the trenches.

In FIG. 8, etch punch out holes in the transparent layer; the layer with the punch-out holes is designated as 1011A.

In FIG. 9, the UV exposure results in gasification and removal of the SiCOH; the SiCOH in the process of being gasified and removed is designated as 1009A. It will accordingly be appreciated that one pertinent issue in one or more embodiments is how to clear material from the bottom dielectric 1007 while building more dielectric on top. In one or more embodiments, the channels are embedded, not open. One or more embodiments accordingly use a sacrificial SiCOH layer that gasifies and then escapes. In this aspect, the sacrificial material is located in the trenches resulting from the first layer of dielectric material being patterned first.

In FIG. 10A, complete dielectric deposition by depositing additional dielectric 1007A. As can be seen in the top view of FIG. 10B, there are broader trenches (T-shaped wider regions 1099T as seen and labeled in FIG. 1) near the holes to prevent complete blockage during the dielectric deposition. In FIG. 10A, consider potential blockage of the channels while depositing the dielectric. To avoid the blockage, one or more embodiments include the broader channel (T-shaped wider regions 1099T T-shaped wider regions 1099T as seen and labeled in FIG. 1) around the punch-out holes.

In FIG. 11, carry out grinding and polishing to reveal the TSVs 1005 (in a non-limiting example, the final thickness can be ˜10 μm). The oxide and Si are polished to obtain a final planar surface.

In FIG. 12, create the TDVs 1005A by etching, depositing a seed layer and liners, plating, and carrying out polishing such as chemical-mechanical planarization. The new vias 1005A on perimeter are used in one or more embodiments for taking power from the packaging substrate to the die. The TDVs 1005A do not necessarily need to be the same size as the inner TSVs 1005; for example, they can be larger to carry current. The skilled artisan will be familiar with etching, seed layers, lining, deposition/plating, and the like, and, given the teachings herein, can form TSVs and TDVs as shown. The vias 1005A can be formed on metal pads 1096, which can be used, for example, for I/O and will be connected to the laminate as discussed below.

In FIG. 13, form under-bump metallization (UBM) 1094 over the vias 1005, 1005A (e.g., deposit Ti and then Cu; the C4 solder bumps are located on top). In one or more embodiments, the pads 1093, 1095 are fine pitch hybrid bonds (of a finer pitch than the UBM). Furthermore in this regard, for illustrative convenience, the TSVs 1005 are depicted as straight with each pair of hybrid bond pads connected to UBM; however, in one or more embodiments, there can be fan-out. Indeed, in one or more embodiments, die 1003 can include an SRAM with active devices that also acts as an interposer with fanout from the hybrid bond.

In FIG. 14, dice the logic wafer as indicated by the vertical lines. Then, flip the wafer and carry out a pick and place operation as seen in FIG. 15. Finally, in FIG. 16, join to the laminate 1015 vis C4 connections (laminate 1015 will typically also include pads for the C4 connections in a conventional manner; these are omitted to avoid clutter in the illustration). Apply underfill 1013, such as non-conductive paste (NCP) or non-conductive film (NCF) in the gap.

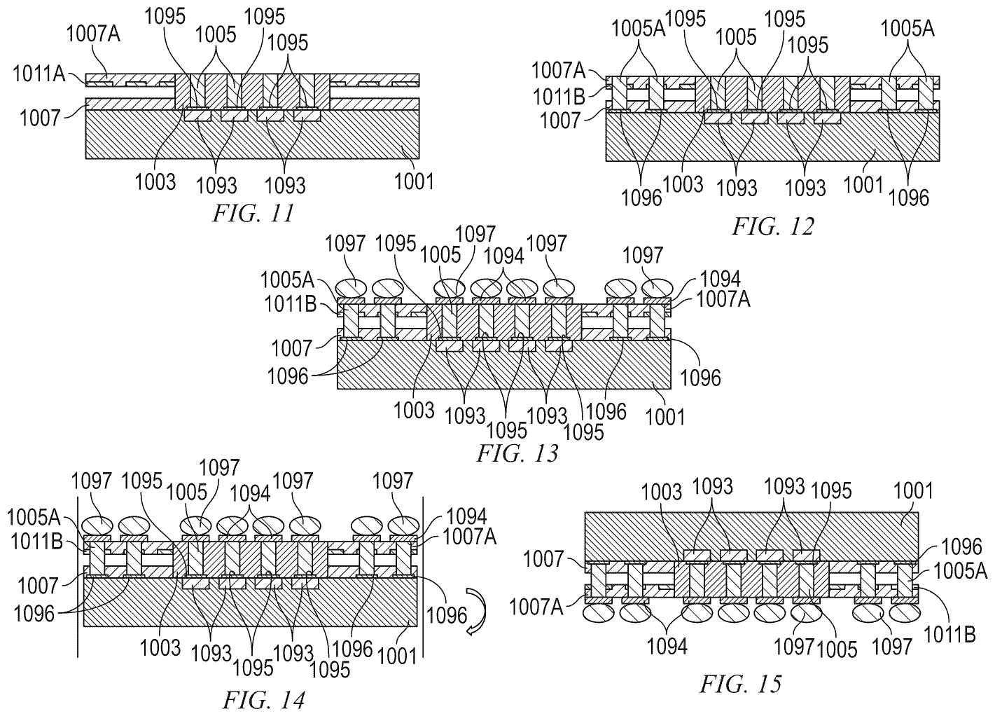

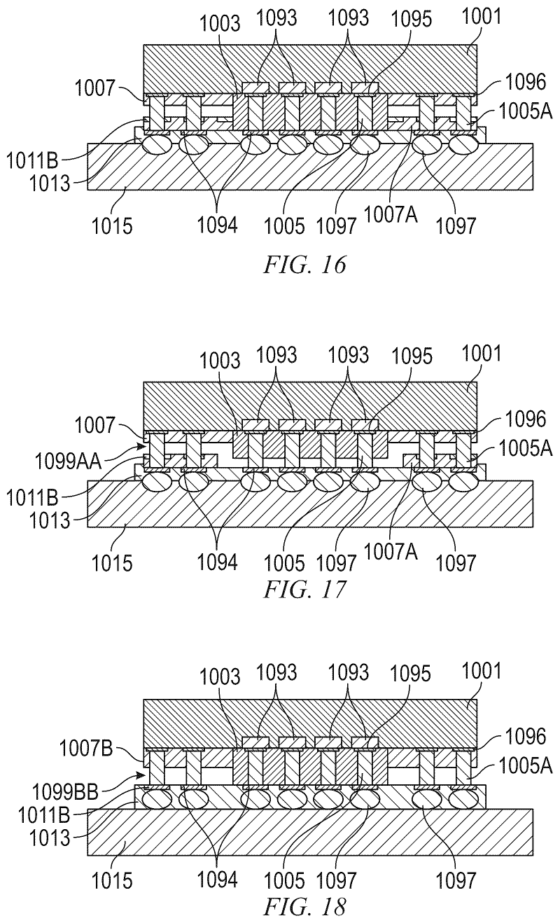

Various other configurations are possible. For example, FIG. 17 shows an embodiment where the cooling channel 1099AA passes under the die 1003. For example, recess the face of the die 1003 during manufacture to provide channel 1099AA. As another non-limiting example, FIG. 18 shows an embodiment where the cooling channel 1099BB is under a single layer of dielectric 1007B. For example, form and recess a single dielectric layer 1007B during manufacture to provide channel 1099BB.

It will accordingly be appreciated that one or more embodiments advantageously permit forming cooling channels in a hitherto unreachable region, such as a smaller die below a larger die, possible also between the larger die and a laminate that is larger than the smaller die. In some cases, the die thickness is less than 60 μm (the thickness value corresponds to each die in the stack; the cooling channels can be present around all dies or select dies in the stack). One or more embodiments advantageously provide cooling channels within a dielectric and a jacket surrounding the die(s). In a non-limiting example, the channel height could be on the order of 10-20 μm.

Note that in another aspect, thermally conductive solid material isolated by the dielectric could be substituted for the fluid coolant.

We have found in thermal simulations that 20 μm channels with a cooling fluid at 20 degrees C. could reduce the top die maximum temperature from around 130 degrees C. to around 70 degrees C. and the bottom die maximum temperature from around 130 degrees C. to around 65 degrees C.

In one or more embodiments, cooling channels are placed within the dielectric. Furthermore, advantageously, in one or more embodiments, cooling can be customized. That is to say, only dies that require additional cooling can be fitted with the micro-channels; other dies can be present in the stacked assembly that do not have cooling channels.

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Given the discussion thus far, it will be appreciated that, in general terms, an exemplary stacked assembly includes a first semiconductor die 1001; a second semiconductor die 1003 secured to the first semiconductor die; and a dielectric (e.g., 1007, 1007A) encasing at least the second semiconductor die. The dielectric defines a cooling channel 1099 having at least one inlet and at least one outlet, and the cooling channel is configured to direct cooling fluid to at least the second semiconductor die.

In some cases (e.g., as in FIG. 3), the cooling channel is defined within the dielectric.

One or more embodiments further include a cooling fluid mover 9999 coupled to at least one of the at least one inlet and the at least one outlet (can be coupled to both in a closed-loop system or to only one in an open loop system, for example). One or more embodiments further include cooling fluid (symbolized by “wave” shapes in FIG. 2 but in general can be liquid or gas) in the cooling channel and the fluid mover.

In a non-limiting example, the first semiconductor die is a logic die and the second semiconductor die is a memory die.

In one or more embodiments, the logic die and the memory die are bonded together using at least metal (e.g., copper) bond pads 1093, 1095 on each of the logic die and the memory die. In some instances, the logic die and the memory die are bonded together using hybrid bonding (i.e., bonding of the pads as well as dielectric bonding between dies 1001, 1003). One or more embodiments further include through-silicon vias 1005 extending from at least some of the metal bond pads on the memory die through the memory die.

In hybrid bonding, a permanent bond combines a dielectric bond (e.g., SiOₓ) with embedded metal (e.g., Cu) to form interconnections. Two semiconductor builds are joined (e.g., two individual wafers that are built separately). They typically require a “pristine” surface (smooth and flat, possibly with some recesses), more so than traditional chemical-mechanical planarization (CMP). The two builds are purposely designed to align. The term “hybrid” refers to the presence of both copper and dielectric. A bond that uses dielectric alone is referred to as fusion bonding (oxide to oxide). Hybrid bonding uses metal to metal connections for the copper. The two builds are brought together and a small heat treatment/annealing process is carried out. The oxides bond together and the metals “anneal,” or almost melt, together, thus fusing the interface into a single bonded part (in some instances, seamlessly; i.e., the interface line disappears). In this aspect, it will be appreciated that the dielectric involved in the hybrid bonding is dielectric of the facing surfaces of dies 1001, 1003, as opposed to 1007, 1007A.

One or more embodiments further include a laminate 1015 soldered to the through-silicon vias using solder bumps 1097.

One or more embodiments further include an underfill 1013 between the memory die and the laminate.

In one or more embodiments the logic die extends horizontally beyond the memory die, and the structure further includes peripheral through-device vias 1005A interconnecting the logic die and the laminate outward of a periphery of the memory die. Note that one or more embodiments may be particularly useful where the second die is smaller than the first die and the laminate and is thus relatively inaccessible to cooling.

As noted, the cooling fluid can be gaseous, in which case the fluid mover can be a fan or blower, or the cooling fluid can be liquid, in which case the fluid mover can be a pump. Accordingly, in a non-limiting example of the gaseous case, the cooling fluid is selected from the group consisting of air, helium, and nitrogen, and the fluid mover is selected from the group consisting of a fan and a blower. Furthermore, in a non-limiting example of the liquid case, the cooling fluid is water and the fluid mover is a pump. Still further, the coolant could in some cases be two-phase (liquid and vapor) and the fluid mover could even be a passive capillary structure such as in a heat pipe or the like.

The dielectric (e.g., 1007, 1007A) can, in some instances, be selected from the group consisting of silicon oxide, silicon nitride, epoxy compound, and molding compound.

One or more embodiments further include a lid 9997 surrounding the first and second semiconductor dies, where the cooling channel (e.g., ductwork) passes through the lid.

Referring, for example, to the alternative of FIG. 17, in some cases, a first side of the second semiconductor die is secured to the first semiconductor die and the cooling channel 1099AA is further configured to direct cooling fluid to a second side of the second semiconductor die opposite the first side of the second semiconductor die.

Referring, for example, to FIG. 1, in some cases, the cooling channel is configured with a plurality of main portions perpendicular to the second semiconductor die and a plurality of secondary portions 1099T transverse to the main portions.

Referring, for example, to the alternative of FIG. 18, in some cases, the dielectric 1007B resides on only an upper side of the cooling channel.

In another aspect, an exemplary method for forming a stacked assembly includes providing a first assembly as shown in FIG. 4, including a first semiconductor die and a second semiconductor die secured to the first semiconductor die, wherein the first semiconductor die extends horizontally beyond the second semiconductor die. Further steps include depositing a first dielectric layer 1007 at least on a peripheral surface of the first semiconductor die; patterning and etching the first dielectric layer to form at least one cooling channel; depositing a sacrificial layer 1009 in the at least one cooling channel; forming a layer of ultraviolet-transparent material 1011 above the at least one cooling channel; applying ultraviolet radiation (see FIG. 9) to the sacrificial layer through the layer of ultraviolet-transparent material to cause gasification and removal of the sacrificial material; and depositing a second dielectric layer 1007A outward of the layer of ultraviolet-transparent material to at least partially enclose the at least one cooling channel, to produce a second assembly (see FIG. 11).

One or more instances of the exemplary method further include hybrid bonding the first and second semiconductor dies to form the first assembly.

Referring to FIGS. 12-16, one or more instances of the exemplary method further include joining the second assembly to a laminate 1015 and providing underfill 1013.

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed backside gate tie-down in backside power distribution network (BSPDN) architecture.

An integrated circuit in accordance with aspects of the present inventions can be employed in essentially any application and/or electronic system where one or more aspects of the disclosed backside gate tie-down in backside power distribution network (BSPDN) architecture would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. A stacked assembly comprising:
a first semiconductor die;
a second semiconductor die secured to the first semiconductor die; and
a dielectric encasing at least the second semiconductor die, wherein the dielectric defines a cooling channel having at least one inlet and at least one outlet, and wherein the cooling channel is configured to direct cooling fluid to at least the second semiconductor die.

2. The stacked assembly of claim 1, wherein the cooling channel is defined within the dielectric.

3. The stacked assembly of claim 2, further comprising a cooling fluid mover coupled to at least one of the at least one inlet and the at least one outlet.

4. The stacked assembly of claim 3, further comprising cooling fluid in the cooling channel and the fluid mover.

5. The stacked assembly of claim 4, wherein the first semiconductor die comprises a logic die and the second semiconductor die comprises a memory die.

6. The stacked assembly of claim 5, wherein the logic die and the memory die are bonded together using at least metal bond pads on each of the logic die and the memory die.

7. The stacked assembly of claim 6, wherein the logic die and the memory die are bonded together using hybrid bonding, further comprising through-silicon vias extending from at least some of the metal bond pads on the memory die through the memory die.

8. The stacked assembly of claim 7, further comprising a laminate soldered to the through-silicon vias using solder bumps.

9. The stacked assembly of claim 8, further comprising an underfill between the memory die and the laminate.

10. The stacked assembly of claim 9, wherein the logic die extends horizontally beyond the memory die, further comprising peripheral through-device vias interconnecting the logic die and the laminate outward of a periphery of the memory die.

11. The stacked assembly of claim 4, wherein the cooling fluid is selected from the group consisting of air, helium, and nitrogen, and wherein the fluid mover is selected from the group consisting of a fan and a blower.

12. The stacked assembly of claim 4, wherein the cooling fluid includes water and wherein the fluid mover comprises a pump.

13. The stacked assembly of claim 4, wherein the dielectric is selected from the group consisting of silicon oxide, silicon nitride, epoxy compound, and molding compound.

14. The stacked assembly of claim 4, further comprising a lid surrounding the first and second semiconductor dies, wherein the cooling channel passes through the lid.

15. The stacked assembly of claim 4, wherein a first side of the second semiconductor die is secured to the first semiconductor die and wherein the cooling channel is further configured to direct cooling fluid to a second side of the second semiconductor die opposite the first side of the second semiconductor die.

16. The stacked assembly of claim 4, wherein the cooling channel is configured with a plurality of main portions perpendicular to the second semiconductor die and a plurality of secondary portions transverse to the main portions.

17. The stacked assembly of claim 1, wherein the dielectric resides on only an upper side of the cooling channel.

18. A method for forming a stacked assembly, comprising:
providing a first assembly including a first semiconductor die and a second semiconductor die secured to the first semiconductor die, wherein the first semiconductor die extends horizontally beyond the second semiconductor die;
depositing a first dielectric layer at least on a peripheral surface of the first semiconductor die;
patterning and etching the first dielectric layer to form at least one cooling channel;
depositing a sacrificial layer in the at least one cooling channel;
forming a layer of ultraviolet-transparent material above the at least one cooling channel;
applying ultraviolet radiation to the sacrificial layer through the layer of ultraviolet-transparent material to cause gasification and removal of the sacrificial material; and
depositing a second dielectric layer outward of the layer of ultraviolet-transparent material to at least partially enclose the at least one cooling channel, to produce a second assembly.

19. The method of claim 18, further comprising hybrid bonding the first and second semiconductor dies to form the first assembly.

20. The method of claim 19, further comprising joining the second assembly to a laminate and providing underfill.
